(19) United States
(12) Patent Application Publication
(10) Pub. No.: US 2025/0392312 A1
(43) Pub. Date: Dec. 25, 2025

(54) METAL STRUCTURE AND CONTROL METHOD FOR CONTROLLING SKYRMION BEHAVIOR

(71) Applicant: UNIST(ULSAN NATIONAL INSTITUTE OF SCIENCE AND TECHNOLOGY), Ulsan (KR)

(72) Inventors: Ki-Suk Lee, Ulsan (KR); Hee-Sung Han, Ulsan (KR); Dae-Han Jung, Ulsan (KR); Ganghwi Kim, Ulsan (KR); Suyeong Jeong, Ulsan (KR)

(73) Assignee: UNIST(ULSAN NATIONAL INSTITUTE OF SCIENCE AND TECHNOLOGY), Ulsan (KR)

(21) Appl. No.: 18/879,726

(22) PCT Filed: Nov. 7, 2022
(86) PCT No.: PCT/KR2022/017383

§ 371 Date: Mar. 10, 2025

(30) Foreign Application Priority Data
Jun. 28, 2022 (KR) 10-2022-0079265

(51) Int. Cl. H03K 19/18; H03K 19/21; H10N 50/10; H10N 50/80

(52) U.S. Cl. CPC H03K 19/18; H03K 19/21; H10N 50/10; H10N 50/80

(57) ABSTRACT

The present disclosure relates to a metal structure applicable to a semiconductor device, and more specifically, to a metal structure or method for controlling a skyrmion. A metal structure according to an embodiment of the present disclosure is characterized by including: a magnetic layer; and a heavy metal layer formed on the magnetic layer, having a convex portion, and guiding movement of a first skyrmion within the magnetic layer.

### TECHNICAL FIELD

The present disclosure relates to a metal structure applicable to a semiconductor device, and more specifically, to a metal structure or a method for controlling skyrmion behavior.

### BACKGROUND ART

As the semiconductor integrated circuits become more highly integrated and better in performance, new microfabrication technologies are continuously being developed. However, in semiconductor devices of the related art, as the degree of integration increases, gate oxide films no longer function as insulating films, and when the width of wiring is reduced to increase the degree of integration, a short circuit occurs in the wiring. In this way, semiconductor devices of the related art have structural limitations due to the increase in current density and there is a limit to increasing the degree of integration.

Furthermore, as it faces limitations such as heat problems due to rapid increase in power consumption, stagnation in information processing speeds, and rapid increases in manufacturing equipment and process costs, new concepts and approaches that break away from the concept of conventional silicon-based devices are being attempted.

Magnetic skyrmions (hereinafter referred to as skyrmions) are vortex-shaped spin structures of which the inside and outside are magnetized in opposite directions, and may be designed to perform logical operations with each digital code corresponding to a case in which a skyrmion exists or does not exist in a memory device.

Furthermore, research is also being conducted on structures for logical operations using skyrmions, but there is a problem that operations may only be performed in relatively limited environments due to the fact that operations are performed using the creation, extinction, and detection of skyrmions, and that logical operations may only be performed when the movement of skyrmions and the time of skyrmion interference are synchronized.

In addition, when skyrmions move on a waveguide, it is not easy to observe the skyrmions while they are moving and to control them, when a driving current is applied.

Therefore, it is to provide a structure for appropriately controlling the behavior of skyrmions and a logical operation method using the structure.

### DISCLOSURE OF INVENTION

### Technical Problem

The embodiment of the present disclosure is intended to solve the above problems, and more specifically, to propose a metal structure or a method of controlling skyrmions.

### Solution to Problem

A metal structure for achieving the task described above may include a magnetic layer; and a heavy metal layer formed in the magnetic layer, having a convex portion, and guiding movement of a first skyrmion within the magnetic layer.

The metal structure may be formed by a zero boundary of interfacial Dzyaloshinskii Moriya Interaction (DMI) within the magnetic layer.

The convex portion may be convex in a direction in which a skyrmion Hall effect occurs, and may be formed so that a second skyrmion is arranged and the second skyrmion is not moved by a spin transfer torque.

The convex portion may be formed so that the second skyrmion is moved by a spin transfer torque corresponding to the second skyrmion and a repulsive force between the first skyrmion and the second skyrmion.

The metal structure for achieving the task described above may include a magnetic layer and a heavy metal layer formed in the magnetic layer, having a convex portion and a concave portion, and guiding movement of an output skyrmion within the magnetic layer, wherein the heavy metal layer determines movement of the output skyrmion based on a repulsive force between the input skyrmion and the output skyrmion and potential energy by the concave portion, and may implement a NAND gate based on the output skyrmion.

The heavy metal layer may include a first waveguide corresponding to the convex portion and a second waveguide corresponding to the concave portion, and an input skyrmion may be positioned at one end of the first waveguide, and an output skyrmion may be positioned at one end of the second waveguide.

In the metal structure, if there is one input skyrmion, the output skyrmion may be positioned at the other end of the second waveguide, and if there are two input skyrmions, the output skyrmion may not be positioned at the other end of the second waveguide.

The heavy metal layer may determine movement of the carry skyrmion based on the repulsive force of the skyrmion and the input skyrmion, and may implement an adder based on the carry skyrmion and the output skyrmion.

The heavy metal layer may include a first waveguide, a second waveguide, and a third waveguide corresponding to the concave portion.

The input skyrmion may be positioned at one end of the first waveguide, the output skyrmion may be positioned at one end of the second waveguide, and the carry skyrmion may be positioned at one end of the third waveguide.

The other end of the first waveguide may have a concave portion, the second waveguide may have a concave portion between one end and the other end, and the third waveguide may have a concave portion between one end and the other end.

In the heavy metal layer, if the input skyrmion is one, the output skyrmion is positioned at the other end of the second waveguide, and the carry skyrmion is not positioned at the other end of the third waveguide, and if the input skyrmion is two, the output skyrmion is not positioned at the other end of the second waveguide, and the carry skyrmion may be positioned at the other end of the third waveguide.

A method of controlling behavior of skyrmions according to the present disclosure to achieve the task described above, the method includes an operation of arranging the second skyrmion at the convex portion, an operation of applying a spin transfer torque to the first skyrmion and the second skyrmion by applying a current to the metal structure, an operation of moving the first skyrmion, and an operation of moving the second skyrmion based on a repulsive force between the first skyrmion and the second skyrmion.

A method of controlling the behavior of a first skyrmion and a second skyrmion using a metal structure to achieve the task described above, the method includes positioning an input skyrmion on one end of a waveguide having a convex portion and positioning an output skyrmion on one end of a second waveguide having a concave portion, applying a current, determining movement of the output skyrmion at the concave portion, based on the repulsive force between the input skyrmion and the output skyrmion and potential energy from the concave portion; performing a NAND logic operation based on whether the output skyrmion is positioned at the other end of the second waveguide.

A method of controlling behavior of a skyrmion to achieve the task described above includes positioning an input skyrmion at one end of a first waveguide having a concave portion at the other end of the first waveguide, and positioning an output skyrmion at one end of a second waveguide having a concave portion, applying a current, determining movement of the output skyrmion at the concave portion, based on a repulsive force between the input skyrmion and the output skyrmion and potential energy from the concave portion, performing an XOR logic operation based on whether the output skyrmion is positioned at the other end of the second waveguide, positioning a carry skyrmion at one end of a third waveguide having a concave portion, determining movement of the carry skyrmion at the concave portion, based on the repulsive forces of the carry skyrmion and the input skyrmion, and performing an addition operation based on whether the carry skyrmion is positioned at the other end of the third waveguide and whether the output skyrmion is positioned at the other end of the second waveguide.

The performing of the addition operation includes, if the input skyrmion is 1, the output skyrmion is positioned at the other end of the second waveguide and the carry skyrmion is not positioned at the other end of the third waveguide and setting the sum value be 1, and if the input skyrmion is 2, the output skyrmion is not positioned at the other end of the second waveguide, the carry skyrmion is positioned at the other end of the third waveguide and setting the sum value be 10.

### Advantageous Effects of Invention

According to an embodiment of the present disclosure, the behavior of a skyrmion may be controlled using a relatively simple structure.

According to another embodiment of the present disclosure, the location of a skyrmion may be controlled.

According to another embodiment of the present disclosure, logical operations may be performed using movement and interference of skyrmions.

### BRIEF DESCRIPTION OF DRAWINGS

FIG. 1 is a schematic diagram showing movement of skyrmions according to the skyrmion Hall effect.

FIG. 2A and FIG. 2B are schematic diagrams showing movement and interference of skyrmions in a waveguide, according to an embodiment of the present disclosure.

FIG. 3A and FIG. 3B are schematic diagrams showing movement and interference of skyrmions over time in a waveguide according to an embodiment of the present disclosure.

FIG. 4A and FIG. 4B are schematic diagrams showing the potential energy of skyrmions in a metal structure according to an embodiment of the present disclosure.

FIG. 5 is a diagram showing a driving current in a metal structure according to an embodiment of the present disclosure.

FIG. 6 is a schematic diagram showing a metal structure according to an embodiment of the present disclosure.

FIG. 7 is a schematic diagram showing a metal structure implementing a convex portion and a concave portion, according to an embodiment of the present disclosure.

FIG. 8A is a schematic diagram showing a NAND logic gate using a metal structure according to an embodiment of the present disclosure.

FIG. 8B to FIG. 8G are schematic diagrams showing operations of a NAND logic gate being driven over time using a metal structure according to an embodiment of the present disclosure.

FIG. 9A is a schematic diagram showing an adder using a metal structure according to an embodiment of the present disclosure.

FIG. 9B to FIG. 9G are schematic diagrams showing operations of an adder being driven over time using a metal structure according to an embodiment of the present disclosure.

FIG. 10 is a flowchart showing a skyrmion control method according to an embodiment of the present disclosure.

FIG. 11 is a flowchart showing a NAND logic gate control method according to an embodiment of the present disclosure.

FIG. 12 is a diagram showing an adder control method according to an embodiment of the present disclosure.

FIG. 13 is a block diagram showing a block configuration of a skyrmion control device according to an embodiment of the present disclosure.

### MODE FOR THE INVENTION

The disclosure may be modified into various forms and may have various embodiments. In this regard, the disclosure will now be made in detail to embodiments, examples of which are illustrated in the accompanying drawings. The advantages, features, and methods of achieving the advantages may be clear when referring to the embodiments described below together with the drawings. However, the disclosure may have different forms and should not be construed as being limited to the descriptions set forth herein.

Hereafter, the disclosure will be described more fully with reference to the accompanying drawings, in which embodiments of the disclosure are shown. In describing the disclosure with reference to drawings, like reference numerals are used for elements that are substantially identical or correspond to each other, and the descriptions thereof will not be repeated.

It will be understood that, although the terms “first”, “second”, etc., may be used herein to describe various elements, these elements should not be limited by these terms but are only used to distinguish one element from another.

In the following embodiments, the singular forms are intended to include the plural forms as well, unless the context clearly indicates otherwise.

It will be further understood that the terms “comprises” and/or “comprising,” when used in this specification, specify the presence of stated features or constituent elements but do not preclude the presence or addition of one or more other features or constituent elements.

In the drawings, thicknesses of layers and regions may be exaggerated or reduced for convenience of explanation. For example, the sizes and thicknesses of elements in the drawings are arbitrarily expressed for convenience of explanation, and thus, the current disclosure is not limited to the drawings.

In describing the disclosure, when practical descriptions with respect to related known function and configuration may unnecessarily make unclear of the scope of the disclosure, the descriptions thereof will be omitted.

Skyrmion according to the present disclosure may refer to a magnetic skyrmion as a spiral-shaped spin structure in which the inside and the outside are magnetized in opposite directions.

A convex portion according to the present disclosure may refer to, in a waveguide through which the skyrmion moves, a region of waveguide that is widened, and a concave portion may refer to, in a waveguide through which the skyrmion moves, a region of waveguide that is narrowed. In the case of the waveguide, it may be widened or narrowed by etching. In addition, the region where the Dzyaloshinskii-Moriya interaction (DMI) effect occurs in the waveguide may be widened or narrowed. This will be described in detail later.

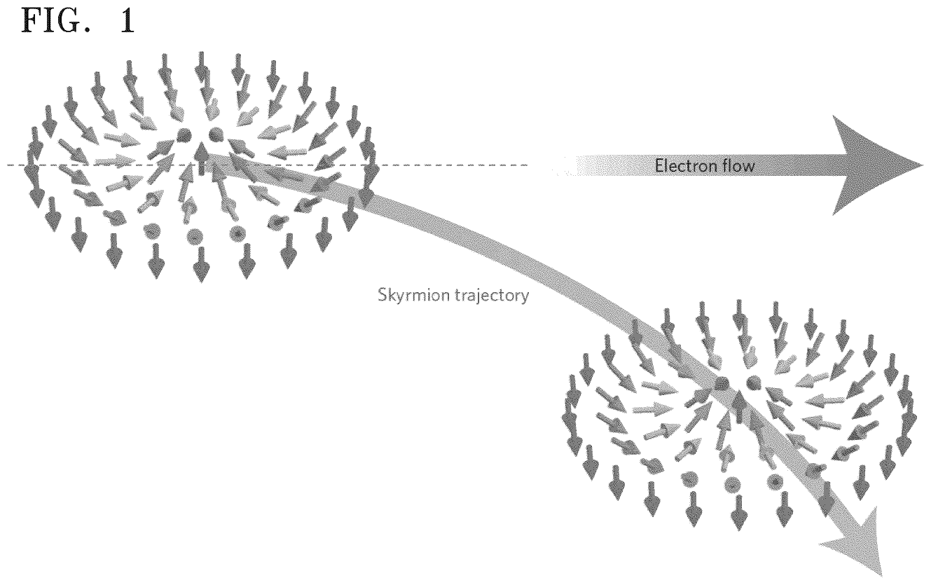

FIG. 1 is a schematic diagram showing movement of a skyrmion according to the skyrmion Hall effect. When a current flows through a magnetic material, the skyimion may may move little by little in a direction of electron movement due to moving electrons. This phenomenon is referred to as spin-transfer torque (STT).

In a magnetic material, the direction of movement of the magnetic structure due to STT is the same as the direction of electron movement. However, in the case of a topological characteristic like a skyrmion, an additional force called the skyrmion Hall effect may be applied in a direction perpendicular to the direction of electron movement. The direction of the skyrmion Hall effect may be determined by a phase of the skyrmion, that is, the direction in which the skyrmion is twisted.

Referring to FIG. 1, if the direction of electron movement is to the right, and the skyrmion phase, that is, the direction in which the skyrmion is twisted, is in a direction from the skyrmion orbit to the origin, the direction of the skyrmion Hall effect may be downward perpendicular to the direction of electron movement.

In contrast, if the twisting direction of the skyrmion having an opposite phase is a direction from the skyrmion origin to the orbit, the direction of the skyrmion Hall effect may be upward perpendicular to the direction of electron movement.

Besides above, the movement trajectory of the skyrmion according to the skyrmion Hall effect may be modified in various ways depending on the type of skyrmion, the magnetization direction, etc.

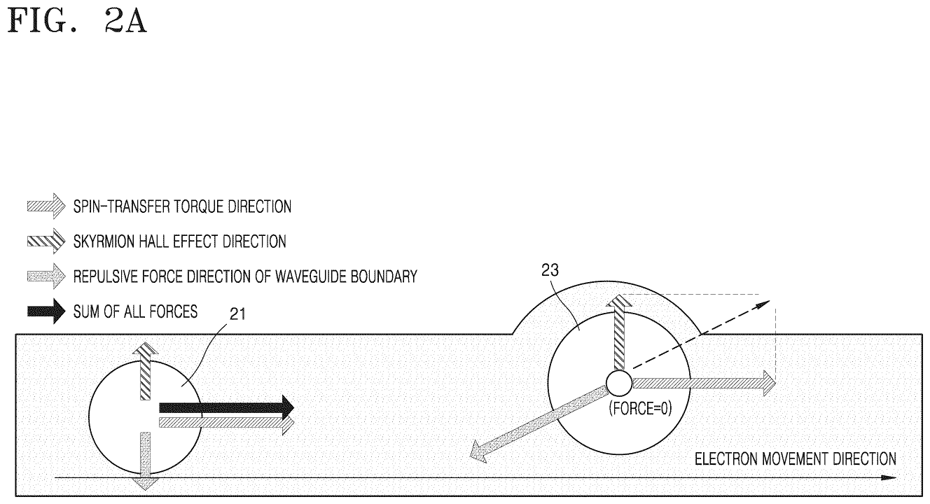

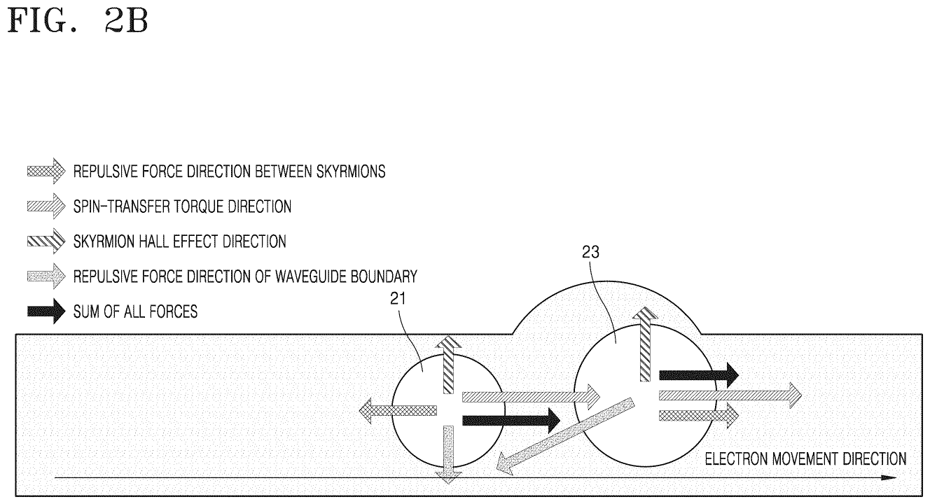

FIGS. 2A and 2B are diagrams showing movement and interference of skyrmions in a waveguide according to an embodiment of the present disclosure, and schematically show the control or restriction of the behavior of skyrmions according to the convex portion according to an embodiment of the present disclosure.

Referring to FIG. 2A, a first skyrmion 21 is positioned at one end of a waveguide, and a second skyrmion 23 is positioned at a convex portion, and then, a current is applied to move electrons.

If the first skyrmion 21 and the second skyrmion 23 are assumed to be sufficiently far apart, if a force affecting the movement of the first skyrmion 21 is examined, the first skyrmion 21 may move in a direction of the electron movement due to a STT according to the movement of the electron, the skyrmion Hall effect, and the repulsive force according to the waveguide boundary.

The second skyrmion 23 receives a force due to the STT according to the movement of the electron, and because the direction of the skyrmion Hall effect is a direction in which the convex portion is formed, the sum of forces applied to the second skyrmion 23 due to the repulsive force of the convex portion waveguide may be 0. Therefore, the movement of the second skyrmion 23 may be restricted.

Referring to FIG. 2B thereafter, according to the movement of the first skyrmion 21, it may be shown that a gap between the first skyrmion 21 and the second skyrmion 23 becomes such that the repulsive force between the skyrmions may not be ignored.

The second skyrmion 23 receives a force due to STT caused by movement of electrons, and because the direction of the skyrmion Hall effect is a direction in which the convex portion is formed, in addition to the force applied to the second skyrmion 23 due to the repulsive force of the convex portion waveguide, the repulsive force of the first skyrmion 21 and the second skyrmion 23 may be applied to the second skyrmion 23. If the sum of the forces applied to the second skyrmion 23 is 0 or greater, the second skyrmion 23 may escape the convex portion and move in the direction of electron movement due to STT.

The first skyrmion 21 may push the second skyrmion 23 away by the repulsive force and may be positioned in the convex portion.

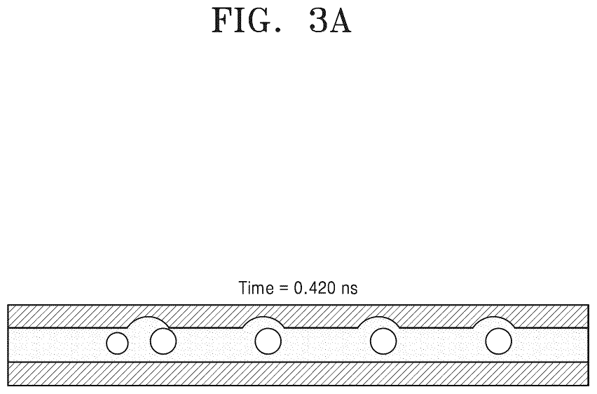

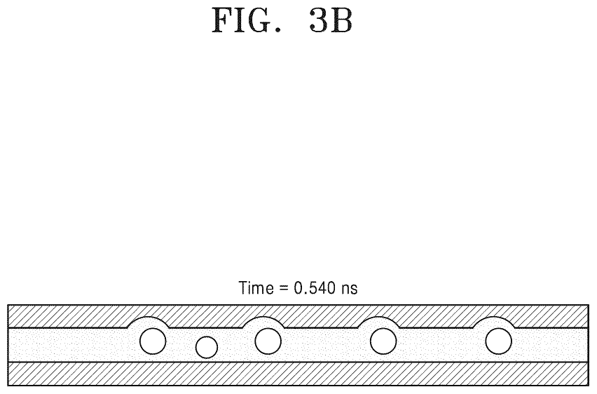

FIG. 3A and FIG. 3B are diagrams showing movement and interference of skyrmions over time in a waveguide according to an embodiment of the present disclosure.

FIG. 3A shows interference between skyrmions at the convex portion when 0.42 ns has passed after a current is applied, and FIG. 3B shows a phenomenon in which the skyrmions positioned at the convex portion move away from the convex portion and move according to the moving direction of electron when 0.54 ns has passed after a current is applied.

In this way, if the convex portions are arranged in a chain on a waveguide and the repulsive force between skyrmions is used, the behavior of skyrmions may be controlled in a chain.

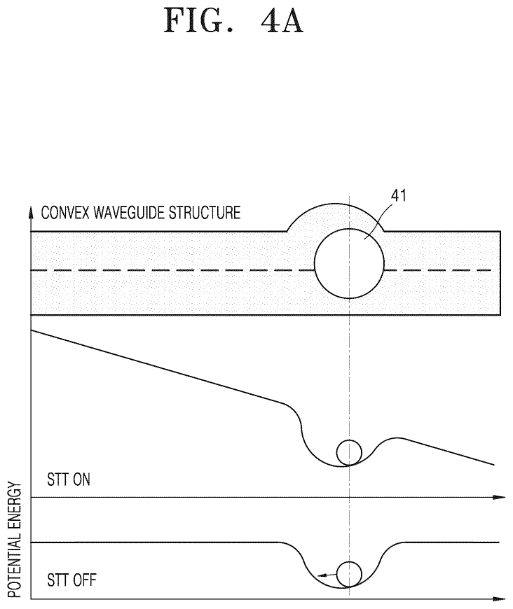

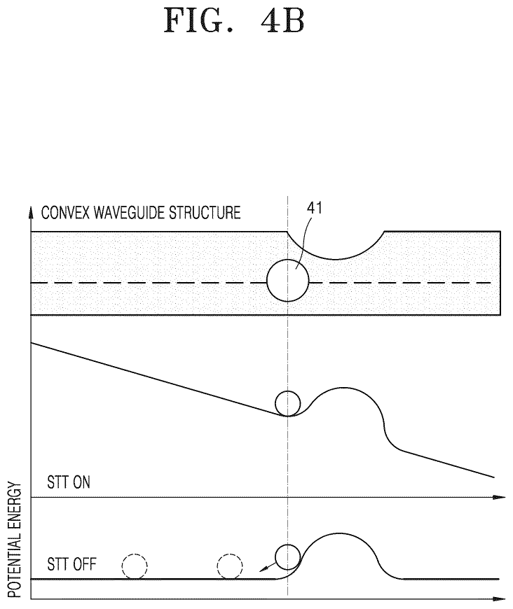

FIGS. 4A and 4B are diagrams showing potential energy for skyrmions in a metal structure according to an embodiment of the present disclosure. FIGS. 4A and 4B are for explaining control of location and movement of skyrmions.

FIG. 4A shows potential energy for a skyrmion positioned at a convex portion. The skyrmion positioned in the convex portion is affected by potential energy from the convex portion. When a current is applied to the skyrmion, a force according to STT is applied to the skyrmion, but if the energy of skyrmion due to STT is not greater than the potential energy, the skyrmion may not escape from the convex portion.

FIG. 4B shows the potential energy for a skyrmion positioned at a concave portion. The skyrmion positioned at a concave portion is affected by the potential energy due to the concave portion. If a current is applied to the skyrmion, a force according to STT is applied to the skyrmion, but if the energy of the skyrmion due to STT is not greater than the potential energy, the skyrmion may not escape from the concave portion. However, in the case of a concave portion, if a current is not applied, the skyrmion may move in a direction where the potential energy is minimized.

In this way, if the skyrmion positioned at a convex portion and a concave portion may be controlled by considering the potential energy and STT, the behavior of the skyrmion may be controlled.

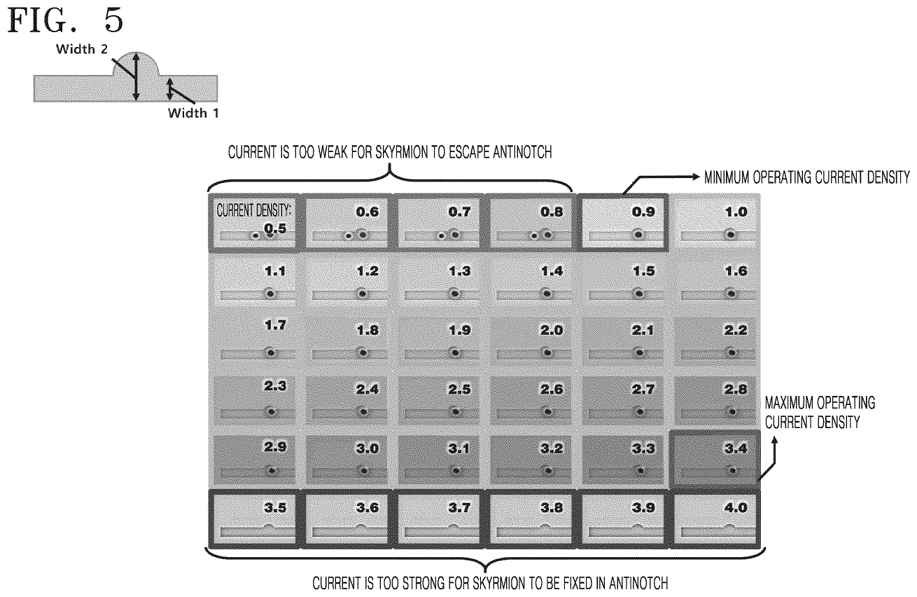

FIG. 5 is a diagram showing a driving current in a metal structure according to an embodiment of the present disclosure. The STT applied to the skyrmion is proportional to the intensity of a current. Therefore, when a convex portion is configured according to an embodiment of the present invention, the driving current that controls the movement of the skyrmion may be confirmed by using the convex portion.

Based on a width 1, which is a width of a waveguide, and a width 2, which is a width of a convex portion, the data measured at intervals of 0.1×10¹² A/m² to obtain a minimum driving current density and a maximum driving current density are as follows.

TABLE 1
Minimum driving current density (unit: 10¹² A/m²)

Width 1

| Width 2 | 30 nm | 40 nm | 50 nm |
|---|---|---|---|
| 40 nm | 0.9 | | |
| 50 nm | 1.0 | 0.7 | |
| 60 nm | 0.7 | 0.9 | Driving |
| | | | impossible |

TABLE 2
Minimum driving current density (unit: 10¹² A/m²)

Width 1

| Width 2 | 30 nm | 40 nm | 50 nm |
|---|---|---|---|
| 40 nm | 3.4 | | |
| 50 nm | 4.0 or | 1.4 | |
| | greater | | |
| 60 nm | 4.0 or | 3.7 | Driving |
| | greater | | impossible |

Table 1 shows the minimum current at which a skyrmion may escape the convex portion by skyrmion interference, and Table 2 shows the maximum current at which a skyrmion may be positioned at the convex portion. The driving current according to the present disclosure may be equal to or greater than the minimum driving current density and equal to or less than the maximum driving current density.

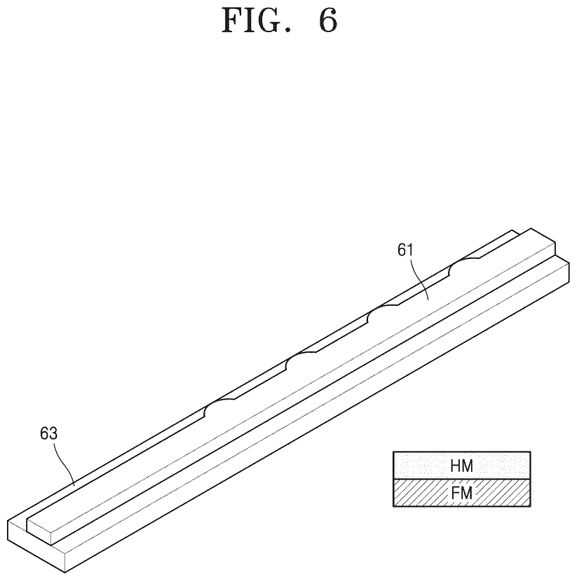

FIG. 6 is a schematic diagram showing a metal structure according to an embodiment of the present disclosure.

The metal structure for controlling skyrmion behavior includes a heavy metal layer 61 and a magnetic layer 63.

The magnetic layer 63 is a material that is strongly magnetized in a direction of a strong magnetic field applied from the outside and remains magnetized even when the external magnetic field disappears. Specifically, the magnetic layer 63 may include an alloy magnetic material such as CoFe, CoFeB, etc. having perpendicular anisotropy, or a Heusler alloy magnetic material such as Co₂FeSi, Co₂MnSi, etc. may be used.

The magnetic layer 63 may be formed as a mono-layer for interfacial DMI or as a multilayer structure through processes, for example, sputtering, molecular beam epitaxy (MBE), atomic layer deposition (ALD), pulse laser deposition (PLD), and an E-beam evaporator. In addition, when interfacial DMI is used, the magnetic layer 63, as a mono-layer structure, may have a thickness in a range, for example, from several Å to several nm, and a line width in a range from, for example, several tens of nm to several μm.

For the heavy metal layer 61 may include one or a mixture of two or more of, for example, platinum, tantalum, iridium, tantalum, hafnium, tungsten, and palladium, and may be formed to a mono-layer structure or a multi-layer structure through a process, for example, sputtering, MBE, ALD, PLD electron beam evaporator, etc. Here, the heavy metal layer 61 may have a thickness, for example, in a range from several nm to several tens nm, and a line width, for example, in a range of several tens nm to several μm.

As described above, the heavy metal layer 61 is formed on the magnetic layer 63, has a convex portion or a concave portion, and may have a waveguide that guides the movement of the first skyrmion 21 in the magnetic layer 63.

The heavy metal layer 61 may be formed to have a plurality of waveguides, and the metal structure according to the present disclosure may implement a digital logic circuit, gate, etc. based on the plurality of waveguides.

The convex portion is convex in a direction in which the skyrmion Hall effect occurs, and the second skyrmion 23 may be arranged. The convex portion is a region in a waveguide to guide movement of the skyrmion, and the movement of the skyrmion may be restricted by using the waveguide repulsion or potential energy.

The convex portion may be formed so that the second skyrmion 23 is not moved by the STT. In addition, the convex portion may be formed so that the second skyrmion 23 is released from the convex portion by the repulsion due to the interference between the first skyrmion 21 and the second skyrmion 23. In addition, the convex portion may be formed so that the first skyrmion 21 is not moved by the STT after the first skyrmion 21 pushes the second skyrmion 23 based on the repulsion. The convex portions may be arranged in multiple numbers on a waveguide.

The convex portion may be concave in a direction in which the skyrmion Hall effect occurs. The convex portion is a region in the waveguide that guides movement of the skyrmion, and the movement of the skyrmion may be restricted using the waveguide repulsive force or potential energy.

The convex portion may be formed so that the skyrmion arranged in the convex portion is not moved by STT. In addition, the convex portion may be formed so that the skyrmion escapes from the convex portion by a repulsive force due to interference between the skyrmions. The convex portion may be arranged in multiple numbers on the waveguide.

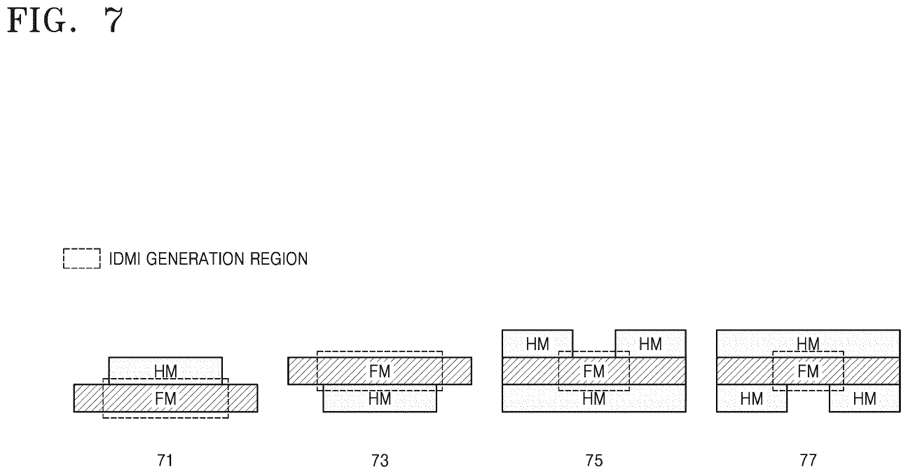

FIG. 7 is a schematic diagram showing a metal structure implementing the convex portion and the concave portion according to an embodiment of the present disclosure.

As described above, the waveguide may be etched to widen or narrow. However, in order to form a waveguide through etching, a process of stacking a heavy metal layer as the first layer, a magnetic layer with a thickness of one atom as the second layer, and a magnetic layer split into two ends as the third layer must be performed, and this structure may have limitations in increasing the integration.

Because the skyrmions may move only in a region where the DMI occurs, a region where the DMI is formed may act as a waveguide.

When reviewing a first metal structure 71 and a second metal structure 73, they may include a magnetic layer and a heavy metal layer formed in a length direction on one side of the magnetic layer while having a line width that is relatively smaller than a line width of the magnetic layer.

By forming only a heavy metal layer on a lower surface of the magnetic layer, skyrmions may be guided, that is, movement (enter and exit) of skyrmions within the magnetic layer may be guided in a longitudinal direction in a state that the magnetic layer and the heavy metal layer are placed in a magnetic field.

The skyrmion may be guided through a potential barrier formed by a DMI zero boundary within the magnetic layer. In other words, movement of the skyrmion may be guided in a length direction of the magnetic layer only within the magnetic layer located directly above the heavy metal layer.

A third metal structure 75 and a fourth metal structure 77 may include a first heavy metal layer, a magnetic layer formed on the first heavy metal layer, and a second heavy metal layer formed on the magnetic layer.

The second heavy metal layer may include a first region A where the second heavy metal layer and the magnetic layer are not bonded, and a second region B where the second heavy metal layer and the magnetic layer are bonded, and a skyrmion may be formed in the first region A on the magnetic layer by the DMI zero boundary.

In this way, when the DMI zero boundary is used, a metal structure having a waveguide including a convex portion and a concave portion may be more easily formed.

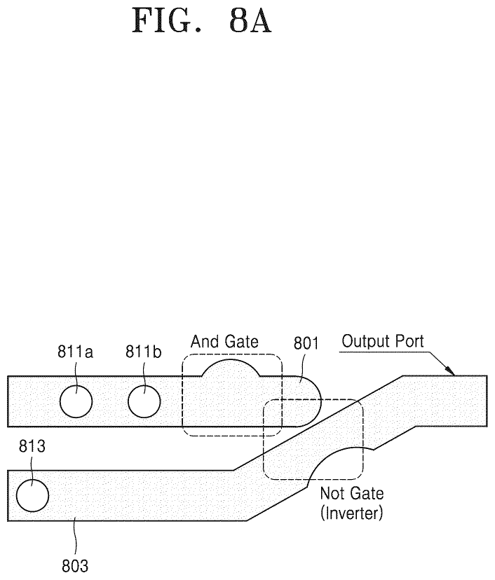

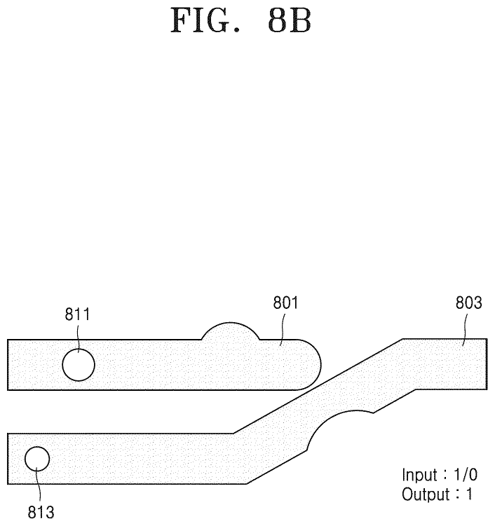

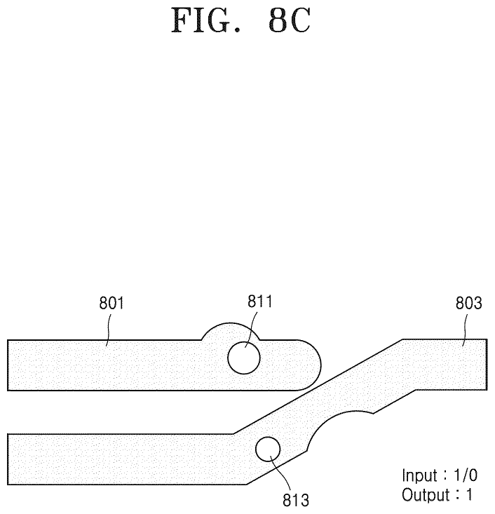

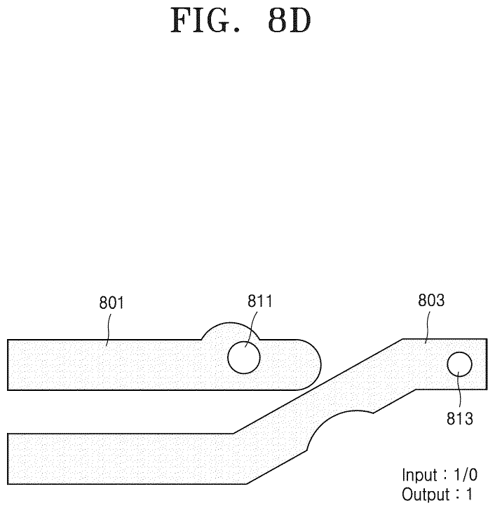

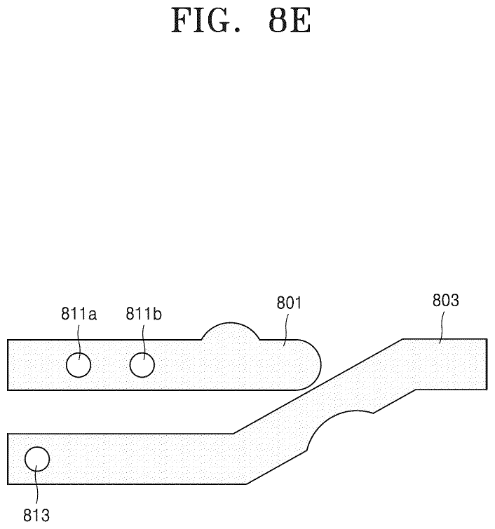

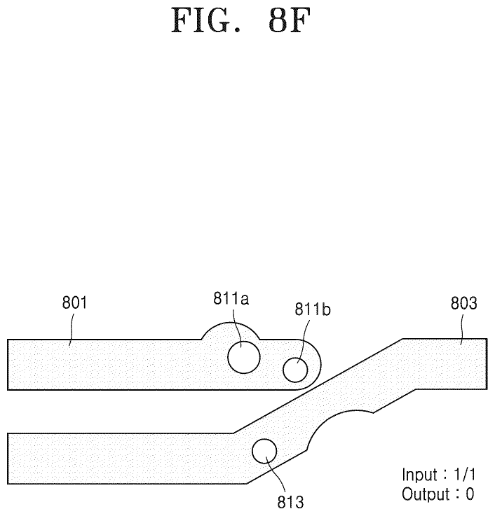

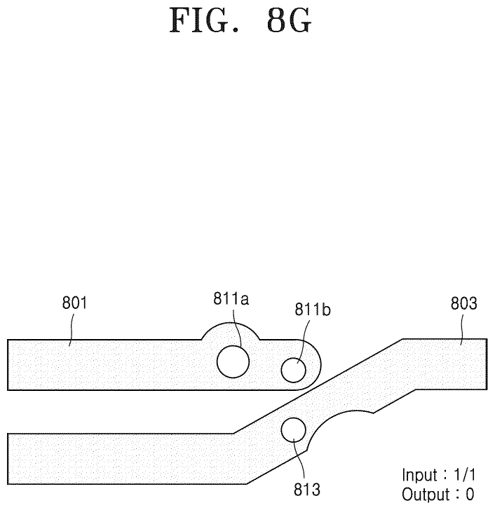

FIG. 8A is a schematic diagram showing a NAND logic gate using a metal structure according to an embodiment of the present disclosure.

The convex portion on the waveguide using the skyrmion may be used as an AND logic gate, and the concave portion may be used as a NOT logic gate.

After arranging input skyrmions 811a and 811b at one end on a first waveguide 801 and arranging an output skyrmion 813 at one end on a second waveguide 803 using the AND gate and NOT gate as described above, a NAND operation may be performed when a current is applied.

Specifically, the heavy metal layer may be formed to determine the movement of the output skyrmion based on a repulsive force between the input skyrmion and the output skyrmion and the potential energy due to the concave portion.

Hereinafter, an operation of a NAND gate using the metal structure will be described. FIGS. 8B to 8G are schematic diagrams showing the operation of the NAND logic gate being driven over time using a metal structure according to an embodiment of the present disclosure.

Referring to FIG. 8B, it may be shown that one input skyrmion 811 is arranged at one end on the first waveguide 801, and the output skyrmion 813 is arranged at one end on the second waveguide 803. Because there is one input skyrmion 811 on the first waveguide 801, the input may mean (1,0). When a driving current is applied to the first waveguide 801, the input skyrmion 811 may move to the convex portion as shown in FIG. 8C, and the output skyrmion 813 may move to the concave portion. If the driving current is continuously applied, as shown in FIG. 8d, the output skyrmion 813 may move away from the concave portion and be positioned at the other end of the second waveguide 803 because the repulsive force with the input skyrmion 811 is not strong enough. At this time, because the output skyrmion 813 reaches the other end of the second waveguide 803, the output may mean 1.

Referring to FIG. 8E, it may be shown that the first input skyrmion 811a and the second input skyrmion 811b are arranged at one end of the first waveguide 801, and the output skyrmion 813 is arranged at one end of the second waveguide 803. Because the first input skyrmion 811a and the second input skyrmion 811b are arranged on the first waveguide 801, the input may mean (1,1). When the driving current is applied to the first waveguide 801, the first input skyrmion 811a may move to the convex portion as shown in FIG. 8F, and the second input skyrmion 811b may move to the other end of the first waveguide 801 where the second input skyrmion 811b may interfere with the output skyrmion 813. The output skyrmion 813 may move to the concave portion. When the driving current is continuously applied to the first waveguide 801, as shown in FIG. 8G, the output skyrmion 813 may not be able to escape from the concave portion due to the repulsive force of the second input skyrmion 811b. Because the output skyrmion 813 did not reach the other end of the second waveguide 803, the output may mean 0.

If this is expressed as a logic circuit truth table, it may be expressed as in Table 3 below.

TABLE 3

Input

| Input 1 | Input 2 | Output |
|---|---|---|
| 1 | 1 | 0 |
| 1 | 0 | 1 |
| 0 | 1 | 1 |
| 0 | 0 | 1 |

Xor Gate

According to the input output of Table 3, it may be confirmed that the logic circuit truth table is a truth table of a NAND gate. In this way, a NAND logic operation may be performed using a metal structure.

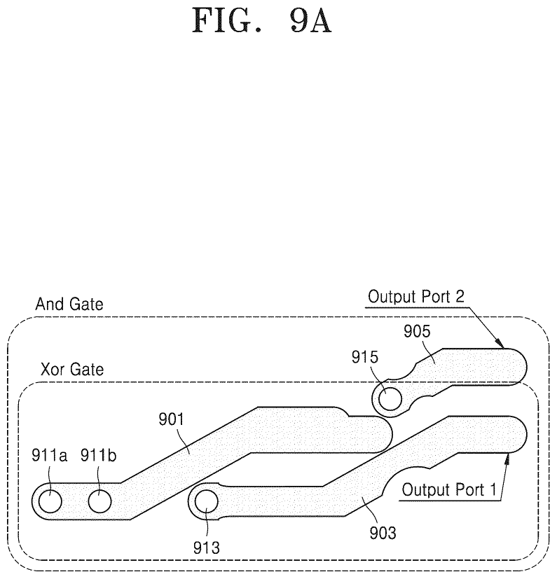

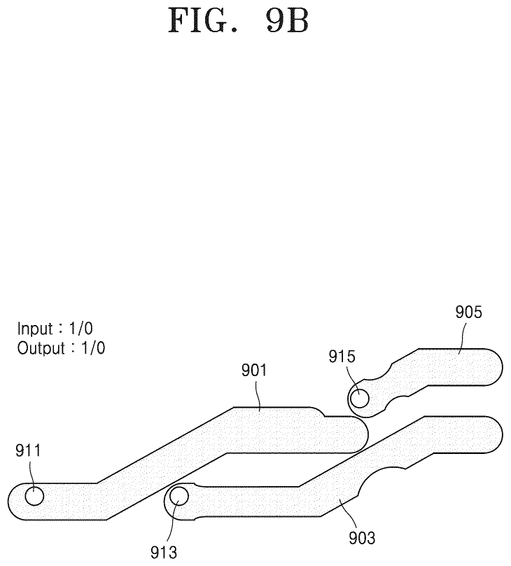

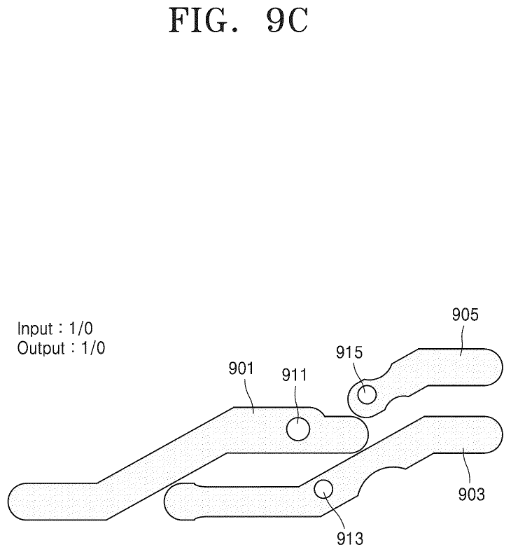

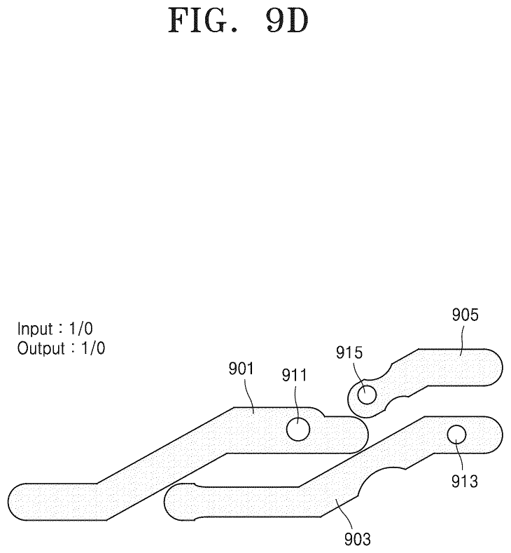

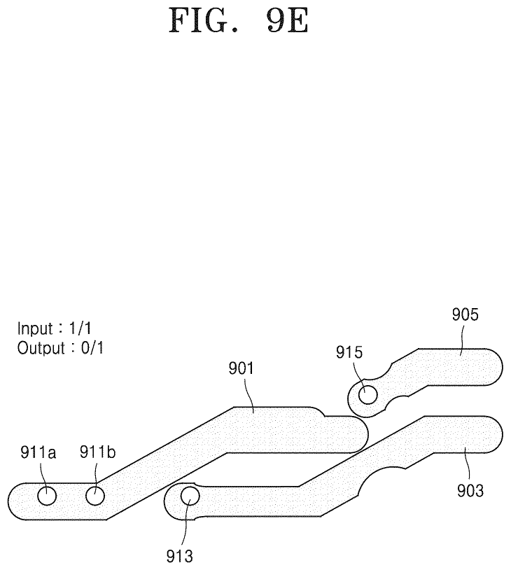

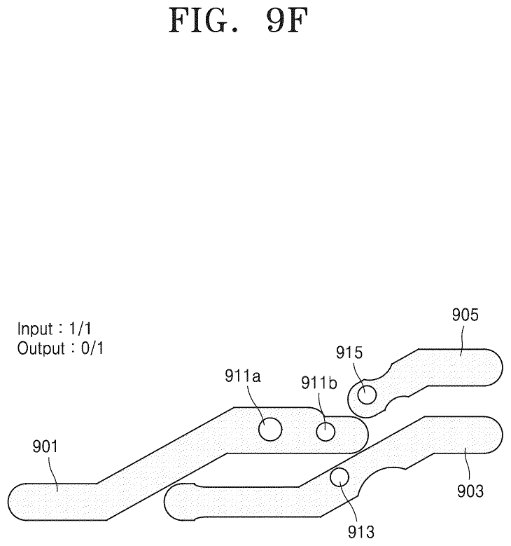

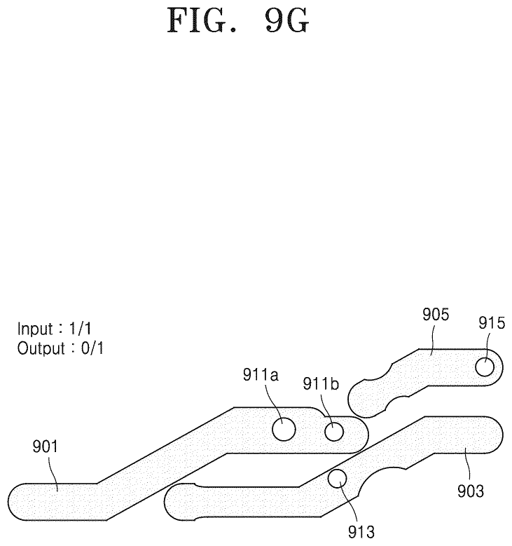

FIG. 9A is a schematic diagram showing an adder using a metal structure according to an embodiment of the present disclosure.

As described above, because a NAND logic operation may be performed using a metal structure, an adder or a half adder may further be implemented using an XOR logic operation and an AND logic operation.

After arranging input skyrmions 911a and 911b at one end of a first waveguide 901 and an output skyrmion 913 or a sum skyrmion at one end of a second waveguide 903, an XOR operation may be performed when a current is applied. In this way, an adder may be implemented by further arranging a carry skyrmion 915 at one end of a third waveguide 905. At this time, the other end of the first waveguide 901 may have a concave portion, and the second waveguide 903 and the third waveguide 905 may have concave portions on the waveguide.

Specifically, the heavy metal layer may determine the movement of the output skyrmion based on the repulsive force of the input skyrmions 911a and 911b and the output skyrmion 913 and the potential energy due to the concave portion, may determine the movement of the carry skyrmion 915 based on the repulsive force of the carry skyrmion 915 and the output skyrmion 913, and may implement an adder based on the carry skyrmion 915 and the output skyrmion 913.

Hereinafter, an operation of the adder using the metal structure will be described. FIGS. 9b to 9g are schematic diagrams showing the operation of an adder being driven over time using a metal structure according to an embodiment of the present disclosure.

Referring to FIG. 9B, it may be shown that one input skyrmion 911 is arranged at one end of the first waveguide 901, one output skyrmion 913 is arranged at one end of the second waveguide 903, and one carry skyrmion 915 is arranged at one end of the third waveguide 905. Because there is one input skyrmion 911 on the first waveguide 901, the input may mean (1,0). When a driving current is applied to the first waveguide 901, the input skyrmion 911 may move to a front end of the concave portion as shown in FIG. 9C, and the output skyrmion 913 may move to a concave portion. If the driving current is continuously applied, as shown in FIG. 9D, the output skyrmion 913 may escape from the concave portion and be positioned at the other end on the second waveguide (903) because repulsive force with the input skyrmion (911) is not sufficiently strong enough. In this case, the carry skyrmion 915 may not escape from the concave portion due to the potential energy of the concave portion on the third waveguide 905. As a result, the output skyrmion 913 reached the other end of the second waveguide 903, and the carry skyrmion 915 did not reach the other end of the third waveguide 905, so the output may mean (1,0).

Referring to FIG. 9E, it may be shown that the first input skyrmion 911a and the second input skyrmion 911b are arranged at one end of the first waveguide 901, the output skyrmion 913 is arranged at one end of the second waveguide 903, and the carry skyrmion 915 is arranged at one end of the third waveguide 905. Because the first input skyrmion 911a and the second input skyrmion 911b are arranged at the first waveguide 901, the input may mean (1,1). When a driving current is applied to the first waveguide 901, the first input skyrmion 911a may move to a front end of the concave portion as shown in FIG. 9F, and the second input skyrmion 911b may move to the other end on the first waveguide 901 where it may interfere with the output skyrmion 913 and the carry skyrmion 915. The output skyrmion 913 may move to the concave portion. If the driving current is continuously applied to the first waveguide 901, as shown in FIG. 9G, the output skyrmion 913 may not be able to escape from the concave portion due to the repulsive force of the second input skyrmion 911b. The carry skyrmion 915 at one end of the third waveguide 905 may escape from the concave portion due to the repulsive force with the second input skyrmion 911b. The carry skyrmion 915 may be positioned at the other end of the third waveguide 905.

Because the output skyrmion 913 did not reach the other end of the second waveguide 903 and the carry skyrmion 915 reached the other end of the third waveguide 905, the output may mean (0,1).

If this is expressed as a logic circuit truth table, it may be expressed as in Table 4 below.

TABLE 4

Output

| | | |
|---|---|---|
| Input | Output1 | Output2 |

| Input1 | Input2 | (Sum) | (Carry) |
|---|---|---|---|
| 1 | 1 | 0 | 1 |
| 1 | 0 | 1 | 0 |
| 0 | 1 | 1 | 0 |
| 0 | 0 | 0 | 0 |

Half Adder

According to the input output of Table 4, it may be confirmed that it is a truth table of a half-adder. In this way, a half-adder operation using a metal structure may be performed.

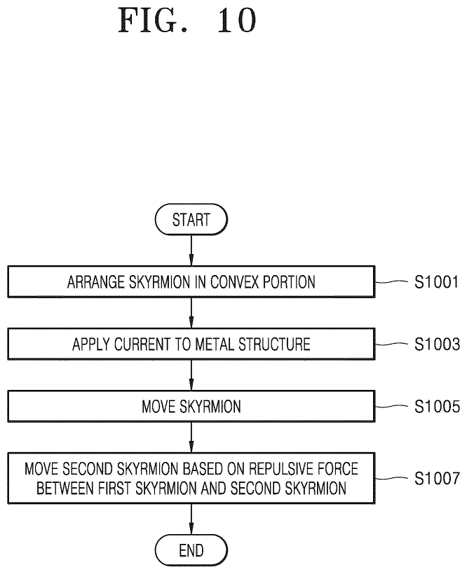

FIG. 10 is a flowchart showing a skyrmion control method according to an embodiment of the present disclosure.

Referring to FIG. 10, in operation S1001, a skyrmion control device may arrange the first skyrmion at one end of a waveguide and the second skyrmion at a convex portion.

In operation S1003, the skyrmion control device may apply a driving current to a metal structure to apply a STT to the first skyrmion and the second skyrmion.

In operation S1005, the skyrmion control device may move the first skyrmion based on the STT. In addition, the skyrmion control device may restrict the movement of the second skyrmion using the convex portion in the metal structure.

In operation S1007, the skyrmion control device may move the second skyrmion based on the repulsive force and STT between the first skyrmion and the second skyrmion.

The skyrmion control device may move the skyrmion positioned at the convex portion in a chain manner in this way. The same method may also be applied to the concave portion.

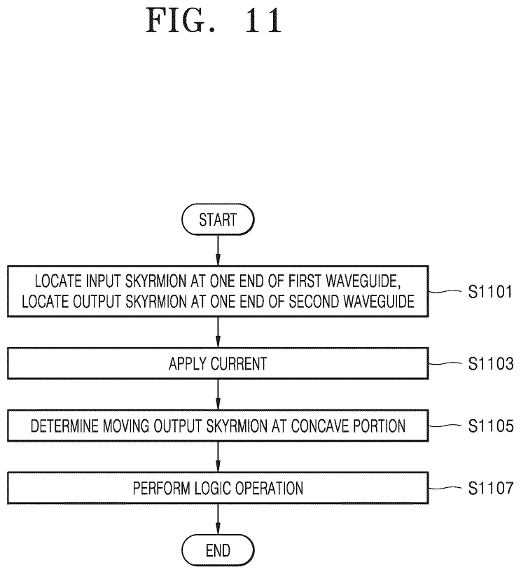

FIG. 11 is a flowchart showing a NAND logic gate control method according to an embodiment of the present disclosure.

In operation S1101, the skyrmion control device may locate the input skyrmion at one end of the first waveguide having the convex portion, and locate the output skyrmion at one end of the second waveguide having the concave portion.

In operation S1103, the skyrmion control device may move the input skyrmion based on the STT. The skyrmion control device may also restrict the movement of the output skyrmion by using the concave portion in the metal structure.

In operation S1105, the skyrmion control device may determine the movement of the output skyrmion in the concave portion based on the repulsive force between the input skyrmion and the output skyrmion and the potential energy due to the concave portion.

In operation S1107, the skyrmion control device may perform a NAND logic operation. For example, the NAND logic operation may be performed based on whether the output skyrmion is positioned at the other end of the second waveguide.

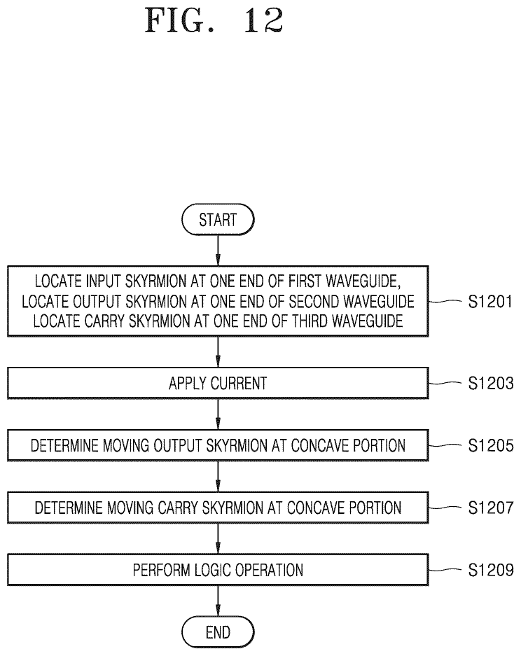

FIG. 12 is a flowchart showing an adder control method according to an embodiment of the present invention.

In operation S1201, the skyrmion control device may locate the input skyrmion at one end of the first waveguide having the concave portion at the other end, locate the output skyrmion at one end of the second waveguide having the concave portion, and locate the carry skyrmion at one end of the third waveguide having the concave portion.

In operation S1203, the skyrmion control device may move the input skyrmion based on the STT. In addition, the skyrmion control device may restrict the movement of the output skyrmion and the carry skyrmion by using the concave portion in the metal structure.

In operation S1205, the skyrmion control device may determine the movement of the output skyrmion in the concave portion based on the repulsive force between the input skyrmion and the output skyrmion and the potential energy due to the concave portion.

In operation S1207, the skyrmion control device may determine the movement of the carry skyrmion in the concave portion based on the repulsive force of the carry skyrmion and the input skyrmion.

In operation S1209, the skyrmion control device may perform an addition operation based on whether the carry skyrmion is positioned at the other end of the third waveguide and whether the output skyrmion is positioned at the other end of the second waveguide.

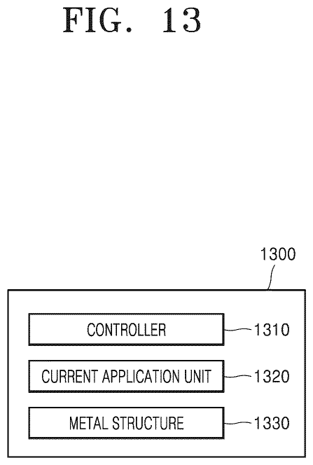

FIG. 13 is a block diagram showing a block configuration of a skyrmion control device 1300 according to an embodiment of the present disclosure. The skyrmion control device 1300 is illustrated as including a controller 1310, a current application unit 1320, and a metal structure 1330, but is not necessarily limited thereto. For example, the controller 1310, the current application unit 1320, and the metal structure 1330 may be physically independent configurations.

The controller 1310 may be a configuration for controlling the skyrmion control device 1300 as a whole. Specifically, the controller 1310 may include a CPU, a RAM, a ROM, a system bus, etc. The controller 1310 may be implemented as a single CPU or multiple CPUs (or DSP, SoC). In one embodiment, the controller 1310 may be implemented as a digital signal processor (DSP), a microprocessor, or a time controller (TCON) that processes digital signals.

For example, the controller 1310 may arrange the second skyrmion at the convex portion, apply a current to the metal structure, move the first skyrmion by applying STT to the first skyrmion and the second skyrmion, and move the second skyrmion based on the repulsive force between the first skyrmion and the second skyrmion.

The current application unit 1320 may apply a driving current to the metal structure for moving the skyrmion.

The metal structure 1330 may include a heavy metal layer and a magnetic layer, and the heavy metal layer may be formed on or lower side of the magnetic layer, may have a convex portion or a concave portion, and may have a waveguide for guiding movement of the skyrmion in the magnetic layer.

The present specification and drawings have disclosed preferred embodiments of the present disclosure, and although specific terms have been used, they have been used only in a general sense to easily explain the technical contents of the present disclosure and to facilitate understanding of the disclosure, and are not intended to limit the scope of the present disclosure. In addition to the embodiments disclosed herein, it will be apparent to those skilled in the art that other modifications based on the technical idea of the present disclosure are possible.

1. A metal structure comprising:
a magnetic layer; and
a heavy metal layer formed on an upper side or a lower side of the magnetic layer, having a convex portion, and guiding movement of a first skyrmion within the magnetic layer.

2. The metal structure of claim 1, wherein
the convex portion is convex in a direction in which a skyrmion Hall effect occurs, and is where a second skyrmion is arranged.

3. The metal structure of claim 2, wherein
the convex portion is formed so that the second skyrmion is not moved by a spin transfer torque corresponding to the second skyrmion.

4. The metal structure of claim 3, wherein
the convex portion is formed so that the second skyrmion is moved by the spin transfer torque corresponding to the second skyrmion and a repulsive force of the first skyrmion and the second skyrmion.

5. The metal structure of claim 1,
being formed by a zero boundary of interfacial Dzyaloshinskii Moriya Interaction (DMI) within the magnetic layer.

6. A metal structure comprising:
a magnetic layer; and
a heavy metal layer formed on the magnetic layer, having a convex portion and a concave portion, and guiding movement of an output skyrmion within the magnetic layer,
wherein the heavy metal layer determines movement of the output skyrmion, based on a repulsive force between an input skyrmion and the output skyrmion and potential energy from the concave portion, and implements a NAND gate, based on the output skyrmion.

7. The metal structure of claim 6, wherein
the heavy metal layer includes: a first waveguide corresponding to the convex portion; and a second waveguide corresponding to the concave portion, and
the input skyrmion is positioned at one end of the first waveguide and the output skyrmion is positioned at one end of the second waveguide.

8. The metal structure of claim 7, wherein,
if the input skyrmion is 1, the output skyrmion is positioned at the other end of the second waveguide, and
if the input skyrmion is 2, the output skyrmion is not positioned at the other end of the second waveguide.

9. The metal structure of claim 6, wherein
the heavy metal layer determines movement of a carry skyrmion, based on a repulsive force of the carry skyrmion and the input skyrmion, and implements an adder, based on the carry skyrmion and the output skyrmion.

10. The metal structure of claim 9, wherein
the heavy metal layer includes a first waveguide, a second waveguide and a third waveguide, corresponding to the concave portion,
the input skyrmion is positioned at one end of the first waveguide, the output skyrmion is positioned at one end of the second waveguide, and
the carry skyrmion is positioned at one end of the third waveguide, and
the other end of the first waveguide has a concave portion, the second waveguide has a concave portion between one end and the other end thereof, and the third waveguide has a concave portion between one end and the other end thereof.

11. The metal structure of claim 10, wherein
if the input skyrmion is 1, the output skyrmion is positioned at the other end of the second waveguide and the carry skyrmion is not positioned at the other end of the third waveguide, and
when the input skyrmion is 2, the output skyrmion is not positioned at the other end of the second waveguide and the carry skyrmion is positioned at the other end of the third waveguide.

12. A method of controlling behavior of a first skyrmion and a second skyrmion by using a metal structure, the method comprising:
arranging the second skyrmion at a convex portion;
applying a spin transfer torque to the first skyrmion and the second skyrmion by applying a current to the metal structure;
moving the first skyrmion; and
moving the second skyrmion, based on a repulsive force between the first skyrmion and the second skyrmion.

13. A method of controlling behavior of a skyrmion by using a metal structure, the method comprising:
positioning an input skyrmion at one end of a first waveguide having a convex portion and positioning an output skyrmion at one end of a second waveguide having a concave portion;
applying a current;
determining movement of the output skyrmion at the concave portion, based on a repulsive force between the input skyrmion and the output skyrmion and potential energy from the concave portion; and
performing a NAND logic operation, based on whether the output skyrmion is positioned at the other end of the second waveguide.

14. A method of controlling behavior of a skyrmion by using a metal structure, the method comprising:
positioning an input skyrmion at one end of a first waveguide having a concave portion at the other end of the first waveguide and positioning an output skyrmion at one end of a second waveguide having a concave portion;
applying a current;
determining movement of the output skyrmion at the concave portion, based on a repulsive force between the input skyrmion and the output skyrmion and potential energy from the concave portion;
performing an XOR logic operation, based on whether the output skyrmion is positioned at the other end of the second waveguide;
positioning a carry skyrmion at one end of a third waveguide having a concave portion;
determining movement of the carry skyrmion at the concave portion, based on a repulsive force of the carry skyrmion and the input skyrmion; and
performing an addition operation, based on whether the carry skyrmion is positioned at the other end of the third waveguide and whether the output skyrmion is positioned at the other end of the second waveguide.

15. The method of claim 14, wherein
the performing of the addition operation includes:
if the input skyrmion is 1, the output skyrmion is positioned at the other end of the second waveguide and the carry skyrmion is not positioned at the other end of the third waveguide, and making a sum value be 1; and
if the input skyrmion is 2, the output skyrmion is not positioned at the other end of the second waveguide, the carry skyrmion is positioned at the other end of the third waveguide and making the sum value be 10.
